(19) United States
(12) Patent Application Publication
(10) Pub. No.: US 2025/0132145 A1
(43) Pub. Date: Apr. 24, 2025

(54) MANUFACTURING METHOD, SUBSTRATE PROCESSING METHOD, AND SUBSTRATE PROCESSING APPARATUS

(71) Applicant: SEMES CO., LTD., Cheonan-si (KR)

(72) Inventors: Do Hyeon YOON, Cheonan-si (KR); Mi So PARK, Cheonan-si (KR); Yong Joon IM, Yongin-si (KR); Hye Bin GWON, Cheonan-si (KR)

(73) Assignee: SEMES CO., LTD., Cheonan-si (KR)

(21) Appl. No.: 18/901,094

(22) Filed: Sep. 30, 2024

(30) Foreign Application Priority Data
Oct. 18, 2023 (KR) 10-2023-0139388

(51) Int. Cl. H01L 21/02; B08B 3/04; B08B 3/08; B08B 7/00; B08B 15/02

(52) U.S. Cl. CPC H01L 21/02057; B08B 3/041; B08B 3/08; B08B 7/0021; B08B 15/02

(57) ABSTRACT

Disclosed is a manufacturing method including: a substrate loading operation of loading a substrate into a liquid treating chamber; a liquid treating operation of supplying a treatment solution to the substrate rotating in the liquid treating chamber through a nozzle; a substrate unloading operation of unloading the substrate from the liquid treating chamber, and a pressure control operation of changing a pressure of a space above the substrate at least one time in a period between the substrate loading operation and the substrate unloading operation.

### CROSS-REFERENCE TO RELATED APPLICATIONS

This application claims priority to and the benefit of Korean Patent Application No. 10-2023-0139388 filed in the Korean Intellectual Property Office on Oct. 18, 2023, the entire contents of which are incorporated herein by reference.

### TECHNICAL FIELD

The present invention relates to a manufacturing method, a substrate processing method, and a substrate processing apparatus.

### BACKGROUND ART

To manufacture semiconductor devices, a desired pattern is formed on a substrate, such as a wafer, through various processes such as photography, etching, ashing, ion implantation, and thin film deposition. Various treatment solutions and treatment gas are used in each process, and particles and process by-products are generated during the process. Cleaning processes are performed before and after each process to remove these particles and process by-products from the substrate.

In the cleaning process, the substrate is cleaned by supplying the substrate with a cleaning solution, such as deionized water. The substrate is then dried to remove any residual cleaning solution on the substrate. One example of a drying treatment is a rotary drying process in which the substrate is rotated at a high speed to remove any residual cleaning solution on the substrate. However, the rotary drying process that rotates the substrate to remove the cleaning solution has the risk of collapsing the pattern formed on the substrate. In addition, as the aspect ratio of the patterns increases, the cleaning fluid introduced between the patterns may not be adequately removed due to the rotation of the substrate. Recently, a supercritical drying process has been utilized in which the residual cleaning solution on the substrate is replaced with an organic solvent, such as isopropyl alcohol (IPA), which has a low surface tension, and the substrate is then supplied with supercritical drying gas (for example, carbon dioxide) to remove the residual organic solvent from the substrate.

However, as the linewidth of the pattern on the substrate becomes finer and the aspect ratio of the pattern becomes larger, there is a growing concern that the pattern formed on the substrate by the IPA may be subjected to a pattern leaning phenomenon, which causes the pattern to collapse, even when the IPA with low surface tension is used. In addition, for effective substrate drying in the supercritical drying processes, it is very important that the thickness of the liquid film formed by the organic solvent being removed is uniform across the substrate. More specifically, when the thickness of the liquid film is not provided uniformly across the substrate, the degree of drying by the supercritical fluid may vary in different areas of the substrate. This may lead to defects in the semiconductor devices manufactured with the substrate.

### SUMMARY OF THE INVENTION

The present invention has been made in an effort to provide a manufacturing method, a substrate processing method, and a substrate processing apparatus that are capable of efficiently treating a substrate.

The present invention has also been made in an effort to provide a manufacturing method, a substrate processing method, and a substrate processing apparatus that are capable of minimizing the problem of collapsing of a pattern formed on a substrate.

The present invention has also been made in an effort to provide a manufacturing method, a substrate processing method, and a substrate processing apparatus that are capable of effectively performing removal of a treatment solution supplied to a substrate.

The object of the present invention is not limited thereto, and other objects not mentioned will be clearly understood by those of ordinary skill in the art from the following description.

An exemplary embodiment of the present invention provides a manufacturing method including: a substrate loading operation of loading a substrate into a liquid treating chamber; a liquid treating operation of supplying a treatment solution to the substrate rotating in the liquid treating chamber through a nozzle; a substrate unloading operation of unloading the substrate from the liquid treating chamber; and a pressure control operation of changing a pressure of a space above the substrate at least one time in a period between the substrate loading operation and the substrate unloading operation

According to the exemplary embodiment, the pressure control operation may include changing the pressure of the space above the substrate to be lowered at least one time.

According to the exemplary embodiment, the manufacturing method may further include a control releasing operation of increasing the pressure of the space above the substrate that was lowered in the pressure control operation.

According to the exemplary embodiment, the pressure control operation may include: (a) reducing a supply rate per unit time of a downflow unit supplying downflow to the space above the substrate; (b) interrupting an operation of the downflow unit; or (c) increasing an exhaust volume per unit time of a treatment space in which the substrate is treated by the treatment solution to cause the pressure in the space above the substrate to be low.

According to the exemplary embodiment, the control releasing operation may be performed after the pressure control operation and before the substrate unloading operation.

According to the exemplary embodiment, the pressure control operation may include disposing a blocking plate in the space above the substrate to block downflow supplied to the space above the substrate to cause the pressure in the space above the substrate to be lowered.

According to the exemplary embodiment, the control releasing operation may be performed after the pressure control operation and before the substrate unloading operation.

According to the exemplary embodiment, the control releasing operation may be performed after the pressure control operation and after the substrate unloading operation.

According to the exemplary embodiment, the blocking plate may be disposed at a height equal to or higher than an entrance opening such that at least a portion of the downflow collides the blocking plate and is directed toward the entrance opening for the substrate provided in the liquid treating chamber.

Another exemplary embodiment of the present invention provides a substrate processing method including: a liquid treating operation of supplying an organic solvent to a substrate rotating in a liquid treating chamber; a transfer operation of transferring the substrate on which the organic solvent is residual from the liquid treating chamber to a drying chamber; and a drying operation of supplying a supercritical fluid from the drying chamber to the substrate, and removing the organic solvent residual on the substrate, in which a pressure control operation of reducing a pressure in a space above the substrate loaded into the liquid treating chamber at least one time during a period between loading of the substrate into the liquid treating chamber and unloading of the substrate from the liquid treating chamber.

According to the exemplary embodiment, the manufacturing method may further include a control releasing operation of increasing the pressure of the space above the substrate that was lowered in the pressure control operation.

According to the exemplary embodiment, the pressure control operation may be performed after the liquid treating operation, the control releasing operation may be performed after the substrate is unloaded from the liquid treating chamber, and the pressure control operation may include: (a) reducing a supply rate per unit time of a downflow unit supplying downflow to the space above the substrate; (b) interrupting an operation of the downflow unit; or (c) increasing an exhaust volume per unit time of a treatment space in which the substrate is treated by the treatment solution to cause the pressure in the space above the substrate to be lowered.

According to the exemplary embodiment, the control releasing operation may be performed before the substrate is unloaded from the liquid treating chamber, and the pressure control operation may include: (a) reducing a supply rate per unit time of a downflow unit supplying downflow to the space above the substrate; (b) interrupting an operation of the downflow unit; or (c) increasing an exhaust volume per unit time of a treatment space in which the substrate is treated by the treatment solution to cause the pressure in the space above the substrate to be lowered.

According to the exemplary embodiment, the control releasing operation may be performed before or after the substrate is unloaded from the liquid treating chamber, and the pressure control operation may include disposing a blocking plate in the space above the substrate to block downflow supplied to the space above the substrate to cause the pressure in the space above the substrate to be lowered.

According to the exemplary embodiment, the organic solvent is isopropyl alcohol.

Still another exemplary embodiment of the present invention provides an apparatus for processing a substrate, the apparatus including: a liquid treating chamber for liquid-treating a substrate; a drying chamber for drying the substrate that has been liquid-treated in the liquid treating chamber; a transfer robot for transferring the substrate between the liquid treating chamber and the drying chamber; and a controller for controlling the liquid treating chamber, the drying chamber, and the transfer robot, in which the liquid treating chamber includes: a rotation plate for supporting and rotating the substrate; a nozzle for supplying a treatment solution to the substrate supported on the rotation plate; and a downflow unit for supplying downflow to the substrate supported on the rotation plate, and the controller generates a pressure control command that causes a pressure in a space above the substrate supported on the rotation plate to be lowered before the substrate loaded into the liquid treating chamber is unloaded.

According to the exemplary embodiment, the pressure control command may be a signal to interrupt an operation of the down flow unit.

According to the exemplary embodiment, the liquid treating chamber may further include a blocking plate disposed above the rotation plate.

According to the exemplary embodiment, the blocking plate may be a blocking plate in which no holes are formed on a surface facing the substrate, and the pressure control signal may be a signal that controls a movement mechanism that moves the blocking plate to face a top surface of the substrate.

According to the exemplary embodiment, the blocking plate may include a first blocking plate having a plurality of first holes formed therein and a second blocking plate having a plurality of second holes formed therein, and the pressure control signal may be a signal controlling a movement mechanism that moves at least one of the first blocking plate and the second blocking plate such that the first holes and the second holes do not overlap, when viewed from above.

According to the exemplary embodiment of the present invention, it is possible to efficiently treat a substrate.

Further, according to the exemplary embodiment of the present invention, the drying treatment efficiency for the substrate may be increased.

Furthermore, according to the exemplary embodiment of the present invention, it is possible to minimize transferring of air pockets to the substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a diagram schematically illustrating a drying chamber of FIG. 1 according to the exemplary embodiment.

FIG. 4 is a flowchart schematically illustrating a substrate processing method according to an exemplary embodiment of the present invention.

FIG. 5 is a diagram illustrating the substrate processing apparatus performing a substrate loading operation of FIG. 4.

FIG. 6 is a diagram illustrating the substrate processing apparatus performing a liquid treating operation of FIG. 4.

FIG. 7 is a diagram illustrating the substrate processing apparatus performing a pressure control operation of FIG. 4.

FIG. 8 is a diagram illustrating the substrate processing apparatus performing a substrate unloading operation of FIG. 4.

FIG. 9 is a diagram illustrating the substrate processing apparatus performing a control releasing operation of FIG. 4.

FIG. 10 is a diagram illustrating capillary force applied to a pattern.

FIG. 11 is a flowchart schematically illustrating a substrate processing method according to another exemplary embodiment of the present invention.

FIG. 12 is a graph schematically illustrating pressure change in a treatment space of the liquid treating chamber when performing the substrate processing method of FIG. 11.

FIG. 13 is a diagram illustrating the substrate processing apparatus performing a pressure control operation according to another exemplary embodiment of the present invention.

FIG. 14 is a diagram illustrating the substrate processing apparatus performing a control releasing operation according to another exemplary embodiment of the present invention.

FIG. 15 is a diagram illustrating the substrate processing apparatus performing a pressure control operation according to another exemplary embodiment of the present invention.

FIG. 16 is a flowchart schematically illustrating a substrate processing method according to another exemplary embodiment of the present invention.

FIG. 17 is a flowchart schematically illustrating a substrate processing method according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the following, the present invention will be described hereinafter based on the fact that a substrate W to be treated is a wafer. Further, the present invention will be described hereinafter based on the fact that a pattern PA is formed on the substrate W to be treated. Further, the present invention will be described based on the fact that a substrate processing method is a method of manufacturing a semiconductor device.

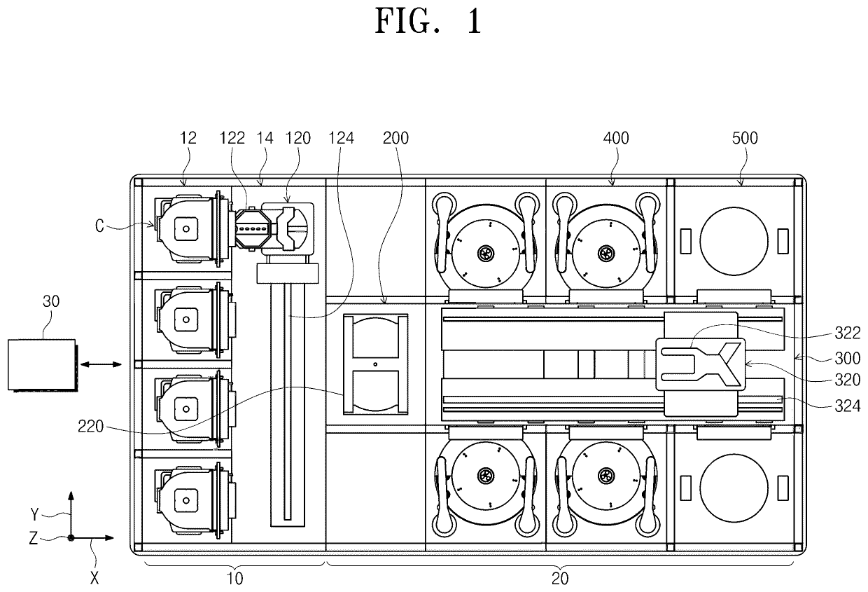

FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

The buffer unit 200 includes a plurality of buffers 220 on which the substrate W is placed. The buffers 220 may be disposed to be spaced apart from each other along the third direction Z. The buffer 220 may be a substrate holder that supports the bottom surface of the substrate W. The buffer 220 may be provided in the form of a support shelf that supports the bottom surface of the substrate W.

A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The controller 30 may control the configurations of the substrate processing apparatus to perform a substrate treating method described below. For example, the controller 30 may generate control commands to control the transfer chamber 300, the liquid treating chamber 400, and the drying chamber 500.

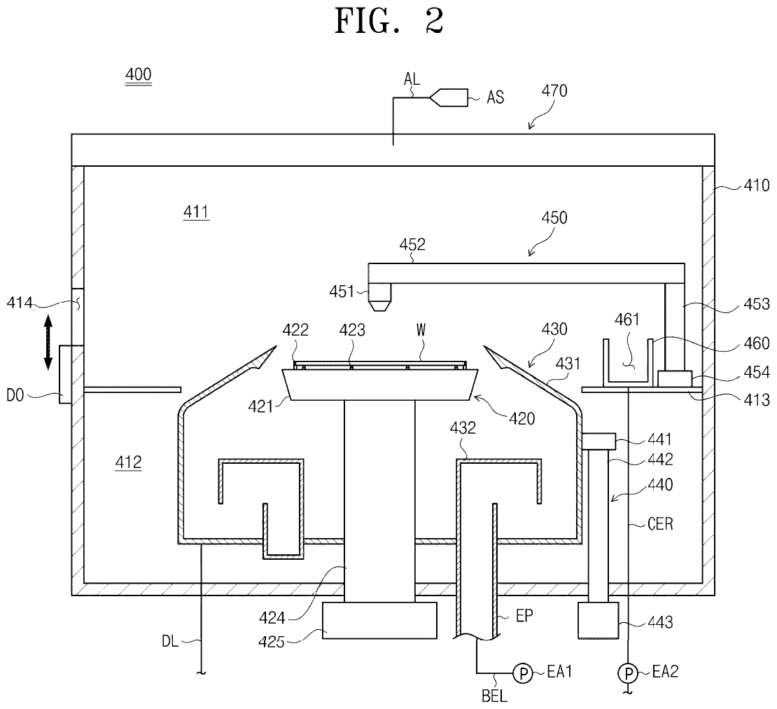

FIG. 2 is a diagram schematically illustrating a liquid treating chamber of FIG. 1 according to an exemplary embodiment.

Referring to FIG. 2, the liquid treating chamber 400 according to the exemplary embodiment of the present invention may treat the substrate W by supplying the substrate W with a treatment solution. The treatment solution supplied to the substrate W may be a cleaning solution that cleans the substrate W. The cleaning solution may be deionized water or an organic solvent. The organic solvent may be a solvent containing alcohol. The organic solvent may be isopropyl alcohol (IPA).

The liquid treating chamber 400 may include a housing 410, a support unit 420, a bowl 430, a lifting unit 440, a liquid supply unit 450, a nozzle standby cup 460, and a downflow unit 470.

The housing 410 may provide a space in which the substrate W is treated, and a space in which some of the configurations of the liquid treating chamber 400 are arranged. The housing 410 may provide an upper space 411, which is a treatment space in which the substrate W is treated, and a lower space 412, which is located below the upper space 411. The upper space 411 and the lower space 412 may be compartmentalized by a compartment plate 413 disposed within the housing 410. The compartment plate 413 may be a plate with an open center region when viewed from above.

On one side of the housing 410, an entrance opening 414 may be formed for the substrate W to be introduced into the upper space 411 and for the substrate W to be removed from the upper space 411. The entrance opening 414 may be selectively opened and closed by a door DO, which may be a shutter. The door DO may be configured to be movable in an up and down direction. For example, the door DO may be configured to be moved in an up and down direction by an electric motor, a pneumatic/hydraulic cylinder, or the like.

The support unit 420 may be configured to support and rotate the substrate W in the space provided by the housing 410. The support unit 420 may include a rotation plate 421, a rotation shaft 424, and a rotation driver 425.

The rotation plate 421 may have a substantially circular plate shape when viewed from above. The rotation plate 421 may have the shape of a top surface that is wide and a bottom surface that is narrow. In the rotation plate 421, a chuck pin 422 and a support pin 423 may be installed. The chuck pins 422 may be provided in plurality.

The chuck pins 422 may be configured to support the bottom face and the side portions of the edge of the substrate W. The chuck pins 422 may be configured to be movable in a direction that is closer to the center of the rotation plate 421 or a direction that is away from the center of the rotation plate 421, when viewed from above. The chuck pins 422 may be configured to be movable in a direction that is closer to the center of the rotation plate 421 or in a direction that is away from the center of the rotation plate 421 by a drive mechanism, such as a motor or cylinder, provided within the rotation plate 421. When the chuck pin 422 is moved in the direction closer to the center of the rotation plate 421 and is positioned in a chucking position, the substrate W may be chucked onto the rotation plate 421. Conversely, when the chuck pin 422 moves in the direction away from the center of the rotation plate 421 and is positioned in a de-chucking position, the substrate W may be de-chucked from the rotation plate 421.

The support pins 423 may be configured to support the bottom face of the substrate W. The support pins 423 may be provided in plurality, and may be configured to support different points on the bottom face of the substrate W, respectively. The support pins 423 may be arranged while being spaced apart from each other along the circumferential direction when viewed from above.

The lower portion of the rotation plate 421 may be coupled with the rotation shaft 424. The rotation shaft 424 may be rotated clockwise or counterclockwise by receiving drive force from the rotation driver 425, which may be a hollow motor.

The bowl 430 may provide a space in which the substrate W is treated. The bowl 430 may have a cup shape with an open top. The bowl 430 may function as a liquid receiving part to collect the treatment solution that is dispersed from the substrate W when the liquid supply unit 450, described later, supplies the treatment solution to the rotating substrate W.

The bowl 430 may include an outer bowl 431 and an inner bowl 432. The outer bowl 431 and the inner bowl 432 may include a bottom portion, a side portion extending upwardly from the bottom portion, and a top portion extending to be sloped from the side portion in a direction closer to the rotation plate 421. The side portion may be coupled with the lifting unit 440 described later. The inner bowl 432 may be a bowl disposed on the inner side of the outer bowl 431. The inner bowl 432 may be connected to an exhaust pipe EP capable of exhausting the downflow DF supplied to the upper space 411 that is the treatment space. The exhaust piping EP may be connected to a first pressure reducing device EA1, which may be a pump, via a bowl exhaust line BEL.

The first pressure reducing device EA1 may be configured to exhaust the atmosphere of the space provided by the housing 410 (e.g., the upper space 411) at all times at a preset exhaust flow rate per unit time.

The treatment solution may be collected between the outer bowl 431 and the inner bowl 432. The collected treatment solution may be discharged to the outside of the liquid treating chamber 400 via a drain line DL connected to the bottom portion of the outer bowl 431.

Additionally, the downflow DF supplied by the downflow unit 470 described later may be exhausted through the space between the outer bowl 431 and the inner bowl 432. The downflow DF may pass between the outer bowl 431 and the inner bowl 432 and be exhausted to the outside of the liquid treating chamber 400 via the exhaust pipe EP and the bowl exhaust line BEL.

The lifting unit 440 may be configured to change the relative height of the bowl 430 and the rotation plate 421. The lifting unit 440 may be configured to move the bowl 430 in an up and down direction, thereby changing the relative height of the bowl 430 and the rotation plate 421. The lifting unit 440 may include a fixing bracket 441, a lifting shaft 442, and a lifting driver 443. The lifting driver 443, which may be a motor, or a pneumatic/hydraulic cylinder, may move the fixing bracket 441 connected to the lifting shaft 442 in the up and down direction. The fixing bracket 441 is coupled to a side portion of the outer bowl 431, and is capable of moving both the outer bowl 431 and the inner bowl 432 in the up and down direction.

The liquid supply unit 450 may supply the substrate W with a treatment solution. The treatment solution may be a cleaning solution that cleans the substrate W. The cleaning solution may be deionized water or an organic solvent. The organic solvent may be a solvent containing alcohol. Furthermore, the organic solvent may be isopropyl alcohol (IPA).

The liquid supply unit 450 may include a nozzle 451, an arm 452, a movement shaft 453, and a movement driver 454. The nozzle 451 may be coupled to the arm 452. The arm 452 may be coupled to the movement shaft 453. The movement shaft 453 may be rotated by the movement driver 454, which may be a motor. The movement shaft 453 may be rotatable. Thus, the arm 452 may be rotatable about an axis of rotation of the movement shaft 453.

The nozzle 451 may change its position between a process position and a standby position by rotation of the movement shaft 453. The process position may be a position at which the nozzle 451 faces the center of the substrate W placed on the rotation plate 421. The standby position may be a position at which the nozzle 451 faces the liquid receiving space 461 of the nozzle standby cup 460 described later.

In the example described above, the liquid supply unit 450 is described and illustrated as being provided with a single liquid supply unit, but the liquid supply unit 450 may be provided with a plurality of liquid supply units. One of the liquid supply units 450 may be configured to supply deionized water, and another may be configured to supply isopropyl alcohol.

The nozzle standby cup 460 may provide a waiting space 461 in which the nozzle 451 may wait. The nozzle 451 may be positioned in the standby position, that is, on the side above the nozzle standby cup 460, when the process is not in progress. The nozzle standby cup 460 may function as a liquid receiving part to receive a pre-discharged treatment solution before the nozzle 451 initiates the process on the substrate W. Additionally, the nozzle standby cup 460 may function as a liquid receiving part to receive the treatment solution that collects at the end portion of the nozzle 451 while the nozzle 451 is waiting.

The nozzle standby cup 460 may be connected with a cup exhaust line CER. The cup exhaust line CER may be connected to a second pressure reducing device EA2, which may be a pump.

The second pressure reducing device EA2 may be configured to exhaust the atmosphere of the space provided by the housing 410 (e.g., the upper space 411) at all times at a preset exhaust flow rate per unit time.

The downflow unit 470 may be installed on the housing 410. The downflow unit 470 may supply downflow DF to a space provided by the housing 410, for example, the upper space 411, which is a treatment space. The downflow unit 470 may be an assembly formed of a fan configured to rotate, a filter disposed at the lower side of the fan, and a frame in which the fan and the filter are installed. The downflow unit 470 may be connected with an air supply line AL that is connected to an air supply source AS. The air supply source AS may supply temperature- and humidity-controlled clean dry air CDA to the downflow unit 470 via the air supply line AL.

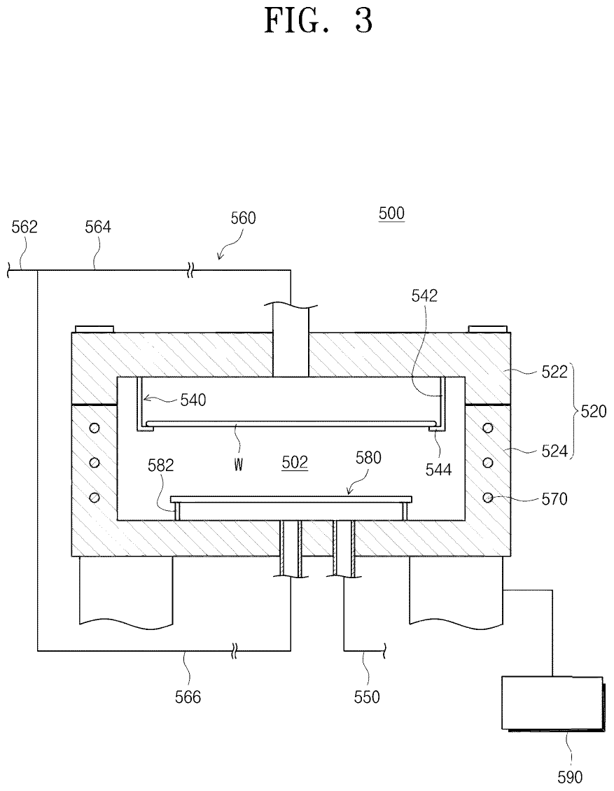

FIG. 3 is a diagram schematically illustrating the drying chamber of FIG. 1 according to the exemplary embodiment.

The drying chamber 500 may provide a supercritical fluid to the substrate W that has been liquid treated in the liquid treating chamber 400 to dry treat the substrate W. In the exemplary embodiment, the drying chamber 500 removes the solution on the substrate W by using a supercritical fluid, which may be carbon dioxide gas in a supercritical state. The drying chamber 500 includes a body 520, a support body 540, a fluid supply unit 560, and a blocking plate 580.

The body 520 provides an internal space 502 in which the drying process is performed. The body 520 includes an upper body 522 and a lower body 524, and the upper body 522 and the lower body 524 are combined with each other to provide the internal space 502 described above. The upper body 522 is provided above the lower body 524. The upper body 522 is fixed in position, and the lower body 524 may be raised and lowered by a drive member 590, such as a cylinder. When the lower body 524 is spaced apart from the upper body 522, the internal space 502 is opened, and in this case, the substrate W is loaded or unloaded. During the process, the lower body 524 is in close contact with the upper body 522, so that the internal space 502 is sealed from the outside.

The drying chamber 500 includes a heater 570. According to one example, the heater 570 is located inside the wall of the body 520. The heater 570 heats the internal space 502 of the body 520 such that the fluid supplied into the internal space 502 of the body 520 maintains a supercritical state.

The support body 540 supports the substrate W in the internal space 502 of the body 520. The support body 540 includes a fixing rod 542 and a cradle 544.

The fixing rod 542 is fixedly installed on the upper body 522 so as to protrude downward from the bottom surface of the upper body 522. The fixing rod 542 is provided so that a longitudinal direction thereof is the vertical direction. A plurality of fixing rods 542 is provided and is positioned to be spaced apart from each other. The fixing rods 542 are disposed so that the substrate W does not interfere with the fixing rods 542 when the substrate W is loaded into or unloaded from the space surrounded by the fixing rods 542. The cradle 544 is coupled to each of the fixing rods 542.

The cradle 544 extends from the lower end of the fixing rod 542 toward the space surrounded by the fixing rods 542. By the above-described structure, the edge region of the substrate W loaded into the internal space 502 of the body 520 is placed on the cradle 544, and the entire top surface area of the substrate W, a central area in the bottom surface of the substrate W, and a part of an edge area in the bottom surface of the substrate W are exposed to the supercritical fluid supplied to the internal space 502.

The fluid supply unit 560 supplies a supercritical fluid to the internal space 502 of the body 520. According to an example, the supercritical fluid may be supplied to the internal space 502 in a supercritical state. Unlike this, the supercritical fluid may be supplied to the internal space 502 in a gaseous state, and may be phase-changed to a supercritical state in the internal space 502. According to the example, the fluid supply unit 560 includes a main supply line 562, an upper branch line 564, and a lower branch line 566.

The upper branch line 564 and the lower branch line 566 are branched from the main supply line 562. The upper branch line 564 is coupled to the upper body 522 to supply the supercritical fluid from the upper portion of the substrate W placed on the support body 540. According to the example, the upper branch line 564 is coupled to the center of the upper body 522.

The lower branch line 566 is coupled to the lower body 524 to supply the supercritical fluid from the lower portion of the substrate W placed on the support body 540. According to the example, the lower branch line 566 is coupled to the center of the lower body 524. An exhaust line 550 is coupled to the lower body 524. The supercritical fluid in the internal space 502 of the body 520 is exhausted to the outside of the body 520 through the exhaust line 550.

A blocking plate 580 may be disposed in the internal space 502 of the body 520. The blocking plate 580 may be provided in a disk shape. The blocking plate 580 is supported by a support 582 so as to be spaced upward from the bottom surface of the body 520. The support 582 is provided in a rod shape, and a plurality of supports 582 is arranged to be spaced apart from each other by a predetermined distance. When viewed from above, the blocking plate 580 may be provided to overlap the outlet of the lower branch line 566 and the inlet of the exhaust line 550. The blocking plate 580 may prevent the substrate W from being damaged due to the direct release of the supercritical fluid supplied through the lower branch line 1490 toward the substrate W.

Hereinafter, a substrate processing method according to an exemplary embodiment of the present invention will be described in detail. The substrate processing method according to the exemplary embodiment of the present invention may include supplying, by the liquid treating chamber 400, a treatment solution, such as isopropyl alcohol, to a rotating substrate W (liquid treating operation), transferring, by the transfer robot 320 of the transfer chamber 300, the substrate W from the liquid treating chamber 400 to the drying chamber 500 while the treatment solution remains on the substrate W (transfer operation), and supplying a supercritical fluid to the substrate W in the drying chamber 500 to remove the treatment solution remaining on the substrate W (drying operation). In the following, the substrate processing method will be described while focusing on the process operations performed in the liquid treating chamber 400.

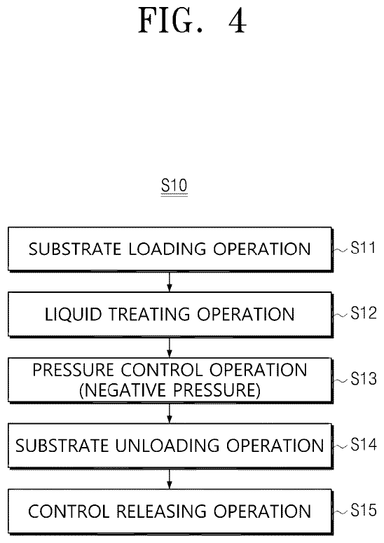

FIG. 4 is a flowchart schematically illustrating a substrate processing method according to an exemplary embodiment of the present invention.

Referring to FIG. 4, a substrate processing method S10 according to a first exemplary embodiment of the present invention may include a substrate loading operation S11, a liquid treating operation S12, a pressure control operation S13, a substrate unloading operation S14, and a control releasing operation S15. The substrate loading operation S11, the liquid treating operation S12, the pressure control operation S13, the substrate unloading operation S14, and the control releasing operation S15 may be sequentially performed.

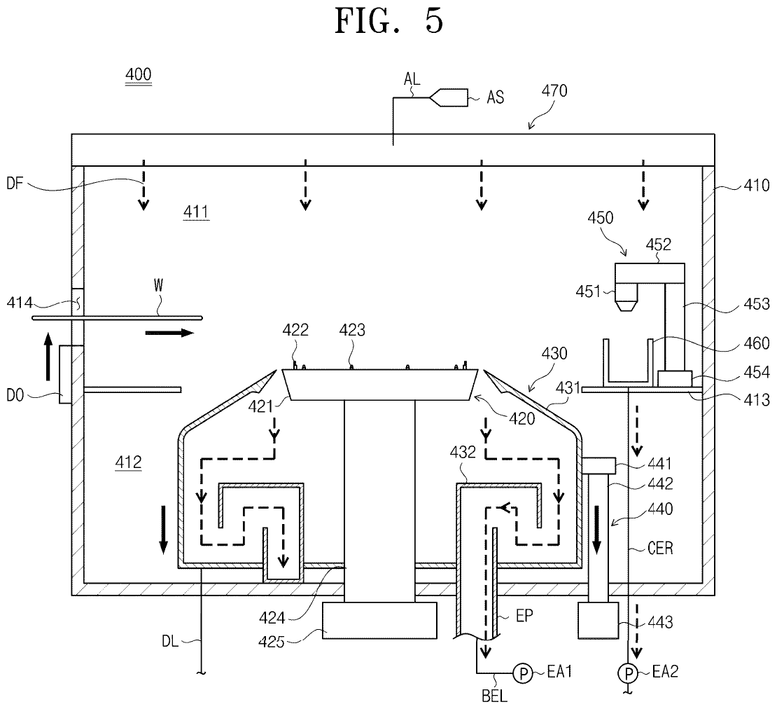

FIG. 5 is a diagram illustrating the substrate processing apparatus performing the substrate loading operation of FIG. 4.

Referring to FIGS. 4 and 5, in the substrate loading operation S11, the door DO opens the entrance opening 414, and the transfer robot 320 of the transfer chamber 300 may load the substrate W into the upper space 411. In the substrate loading operation S11, the nozzle 451 may be positioned in a standby position and the bowl 430 may be positioned in a lowered position.

In the substrate loading operation S11, the downflow unit 470 may supply the downflow DF at a preset supply flow rate per unit time, and the first pressure reducing device EA1 and the second pressure reducing device EA2 may exhaust the downflow DF at a preset exhaust flow rate per unit time. At this time, the pressure in the upper space 411 may be normal pressure.

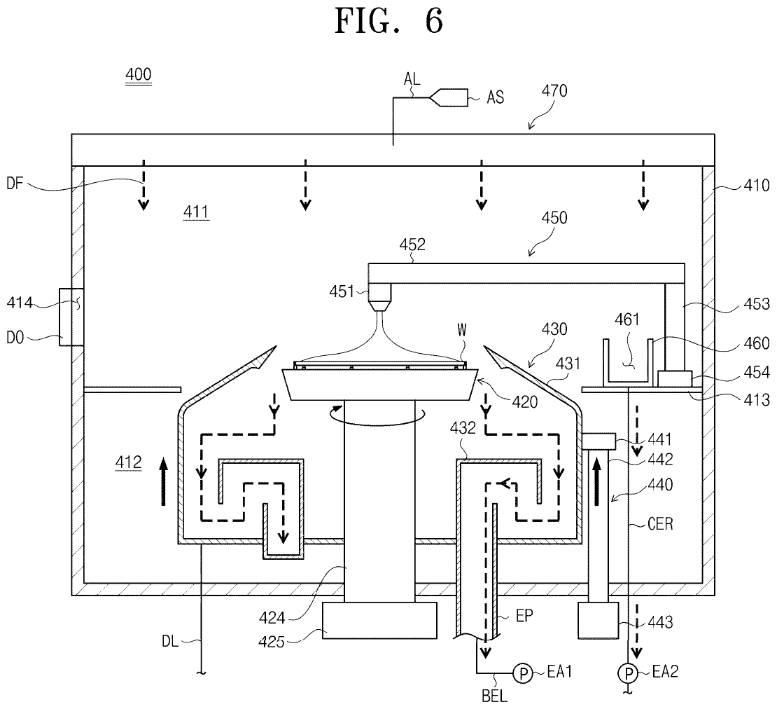

FIG. 6 is a diagram illustrating the substrate processing apparatus performing the liquid treating operation of FIG. 4.

Referring to FIGS. 4 and 6, the liquid treating operation S12 may include supplying, by the nozzle 451 of the liquid supply unit 450, the treatment solution to the rotating substrate W. The treatment solution supplied by the nozzle 451 may be deionized water, or isopropyl alcohol. Here, the treatment solution supplied by the nozzle 451 is isopropyl alcohol.

In this case, the downflow unit 470 may supply the downflow DF at a preset supply flow rate per unit time, and the first pressure reducing device EA1 and the second pressure reducing device EA2 may exhaust the downflow DF at a preset exhaust flow rate per unit time. The supply flow rate per unit time of the downflow unit 470 and the exhaust flow rate per unit time of the first pressure reducing device EA1 and the second pressure reducing device EA2 may be substantially matched. Accordingly, the pressure in the upper space 411 may be maintained at normal pressure. Further, because the downflow DF flows in a downward direction, the top of the substrate W may be subjected to constant pressure by the downwardly flowing downflow DF.

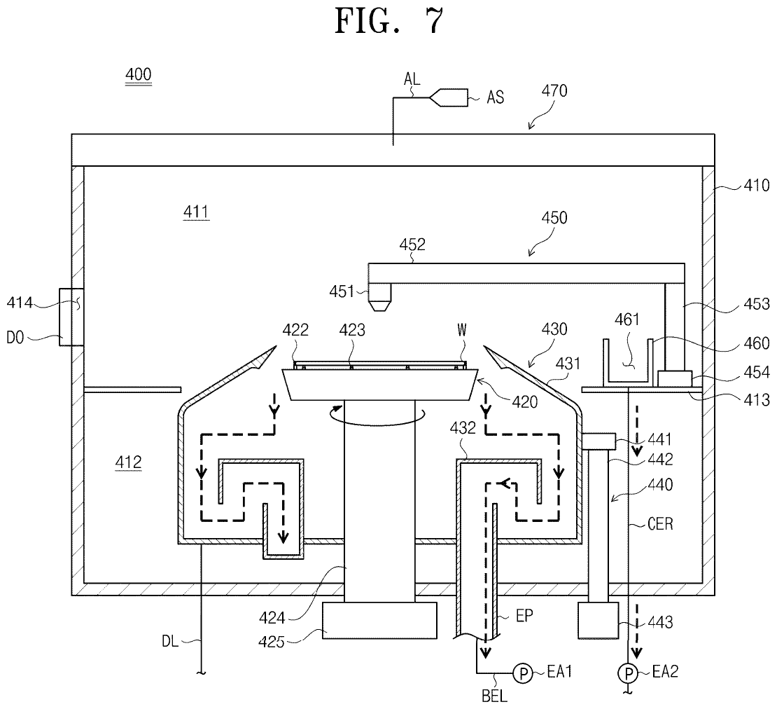

FIG. 7 is a diagram illustrating the substrate processing apparatus performing the pressure control operation of FIG. 4.

Referring to FIGS. 4 and 7, when the liquid treating operation S12 is terminated, the pressure control operation S13 may be performed. In the pressure control operation S13, the operation of the downflow unit 470 may be interrupted, and/or the supply rate per unit time of the downflow unit 470 may be lowered. In this case, the first pressure reducing device EA1 and the second pressure reducing device EA2 may exhaust the downflow DF at a preset exhaust flow rate per unit time. In other words, since the first pressure reducing device EA1 and the second pressure reducing device EA2 still exhaust the downflow DF at the preset exhaust flow rate per unit time with no supply flow rate per unit time or a reduced supply flow rate per unit time of the downflow unit 470, the pressure in the upper space 411 may change to a negative pressure, which is a pressure that is a certain level lower than the normal pressure. As used herein, the negative pressure may be defined as a pressure lower than normal pressure.

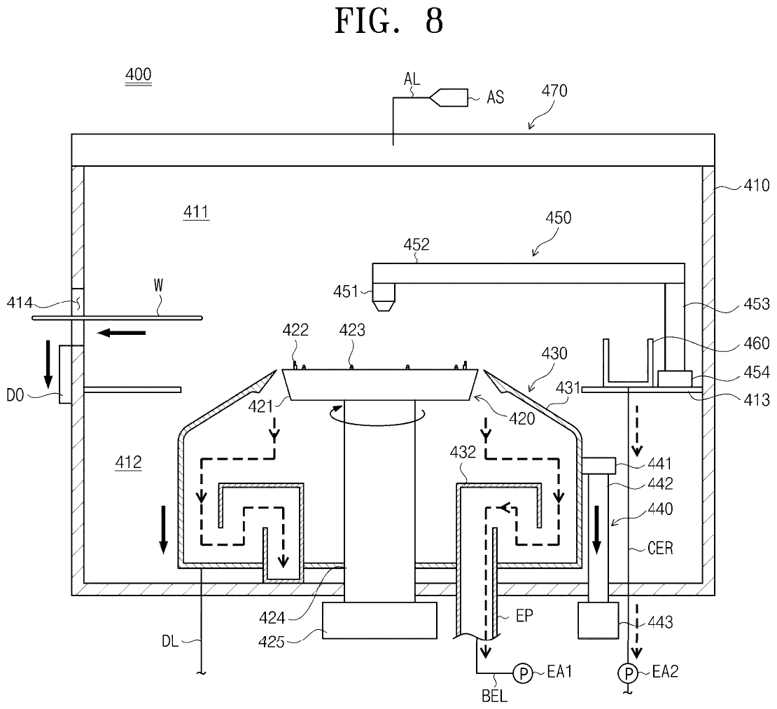

FIG. 8 is a diagram illustrating the substrate processing apparatus performing the substrate unloading operation of FIG. 4.

Referring to FIGS. 4 and 8, when the pressure control operation S13 is terminated, the substrate unloading operation S14 may be performed. In the substrate unloading operation S14, the bowl 430 may be lowered and the door DO may open the entrance opening 414. Thereafter, the transfer robot 320 of the transfer chamber 300 may transfer the substrate W in the liquid treating chamber 400 through the entrance opening 414 and return the substrate W to the drying chamber 500.

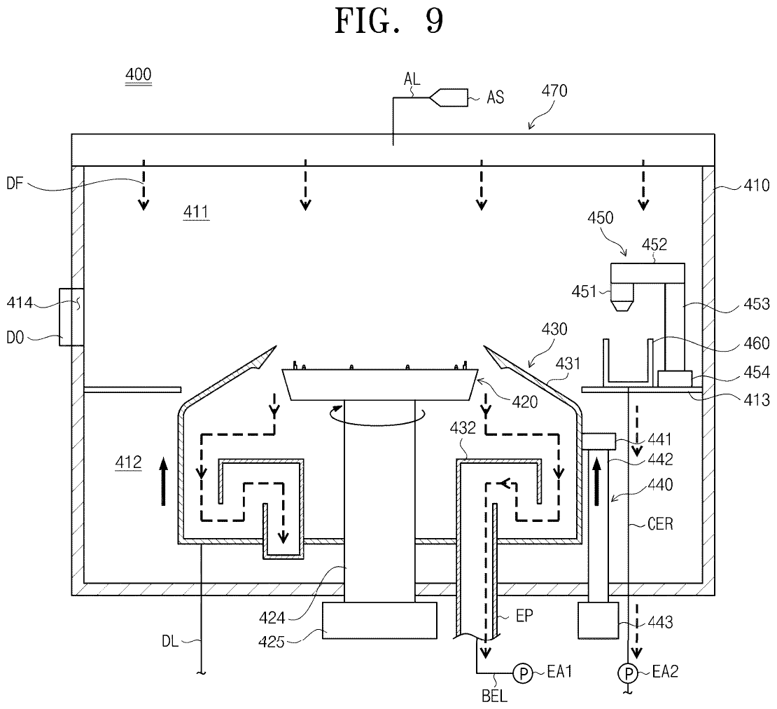

FIG. 9 is a diagram illustrating the substrate processing apparatus performing the control releasing operation of FIG. 4.

Referring to FIGS. 4 and 9, when the substrate unloading operation S14 is terminated, the control releasing operation S15 may be performed. The control releasing operation S15 may include returning the operation of the downflow unit 470 to a state prior to the pressure control operation S13 being performed. For example, when the operation of the downflow unit 470 is interrupted in the pressure control operation S13, the control releasing operation S15 may include restarting the operation of the downflow unit 470. Also, when the supply flow rate per unit time of the downflow DF of the downflow unit 470 is lowered in the pressure control operation S13, the supply flow rate per unit time of the downflow DF of the downflow unit 470 may be increased large in the control releasing operation S15.

According to the exemplary embodiment of the present invention, in the pressure control operation S13, the space above the substrate W placed on the rotation plate 421 is changed at least once. More specifically, the pressure control operation S13 is performed in the period between the substrate loading operation S11 and the substrate unloading operation S14 to change the pressure of the space above the substrate W to be lower than the normal pressure. This is to minimize the problem that the pattern PA formed on the substrate W is collapsed by the pressure caused by the downflow DF supplied to the upper portion of the substrate W.

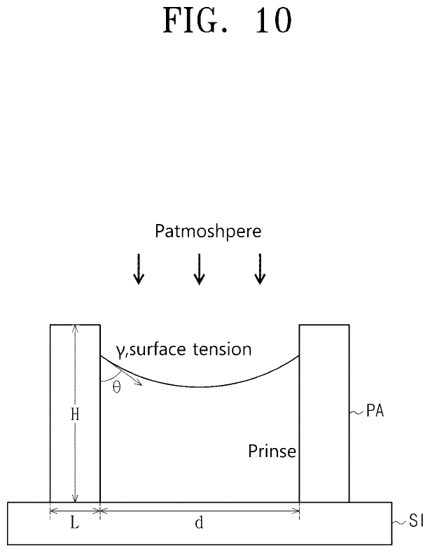

More specifically, FIG. 10 is an enlarged view of one portion of the substrate W. The substrate W may include polysilicon (SI) and a pattern PA formed on the polysilicon (SI).

The linewidth of the pattern PA is indicated by L, the height of the pattern PA is indicated by H, and the spacing between the pattern PA is indicated by d. In addition, when the treatment solution is supplied between the patterns PAs, the treatment solution is in contact with the sidewalls of the PAs. The contact angle of the treatment solution with the sidewalls of the PAs is indicated by θ. In addition, the surface tension of the treatment solution is indicated by γ.

Capillary Force, which is the force that pulls the PAs towards the area where the treatment solution is applied, is given by Equation 1 below.

$$σ = ( 2 γ cos θ ) / d \qquad [ Equation 1 ]$$

In other words, it is important to use a treatment solution with low surface tension in the first place to avoid pattern PA collapse due to capillary force. In addition, it is important to ensure that the contact angle θ between the treatment solution and the sidewalls of the PA is close to 90 degrees. The contact angle θ is determined by the pressure Prinse of the treatment solution and the pressure Patmosphere of the space above the substrate W. When the pressure Prinse of the treatment solution is determined, it is necessary to eliminate the influence of the pressure Patmosphere of the space above the substrate W in order to make the contact angle θ close to 90 degrees.

Therefore, in the present invention, the pressure control operation S13 is performed after the liquid treating operation S12 to reduce the pressure in the space above the substrate W. This allows the contact angle θ to be close to 90 degrees, thereby minimizing the occurrence of pattern collapse caused by the treatment solution. Furthermore, reducing the pressure in the space above the substrate W helps the thickness of the liquid film formed by the treatment solution supplied on the substrate W to be formed and maintained relatively uniformly over the entire area of the substrate W. As the thickness of the liquid film formed on the substrate W is formed and maintained at a relatively constant level, the drying efficiency of the substrate W in the drying chamber 500 may also be improved more dramatically.

In the above-described example, the present invention has been described based on the case where the control releasing operation S15 is performed after the substrate unloading operation S14 is performed as a way of example, but is not limited thereto. For example, when the pressure drop in the pressure control operation S13 is large, Impurities, such as particles, remaining in the transfer chamber 300 may be introduced into the upper space 411 through the entrance opening 414 when the entrance opening 414 is opened while the pressure in the upper space 411 is reduced (at this time, the pressure in the transfer chamber 300 may be maintained at normal pressure).

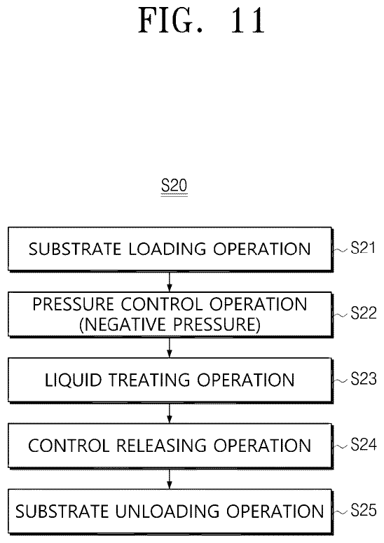

To avoid the introduction of the impurities, a substrate treating method S20 according to another exemplary embodiment of the present invention, as illustrated in FIG. 11, may sequentially perform a substrate loading operation S21, a pressure control operation S22, a liquid treating operation S23, a control releasing operation S24, and a substrate unloading operation S25.

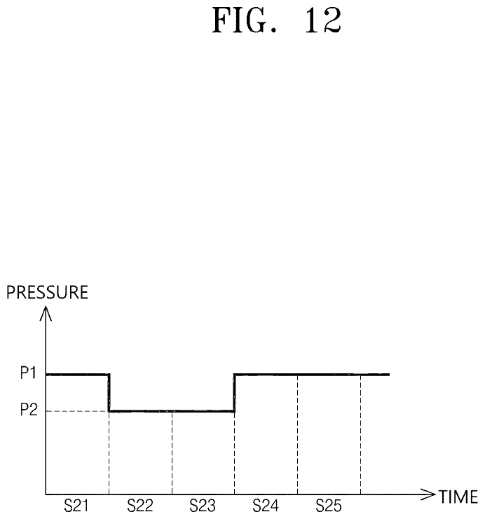

Furthermore, as may be seen with reference to FIG. 12, the pressure in the upper space 411 may be maintained at a first pressure P1, which is normal pressure, during the substrate loading operation S21, the control releasing operation S24, and the substrate unloading operation S25, and the pressure in the upper space 411 may be maintained at a second pressure P2, which is a pressure lower than the normal pressure, during the pressure control operation S22 and the liquid treating operation S23.

In other words, the substrate treating method S20 according to another exemplary embodiment of the present invention may first perform the control releasing operation S24 and then perform the substrate loading operation S25 to convert the pressure in the upper space 411 to normal pressure before the substrate W is unloaded. Accordingly, impurities, such as particles, remaining in the transfer chamber 300 may be minimized from being introduced into the upper space 411 through the entrance opening 414.

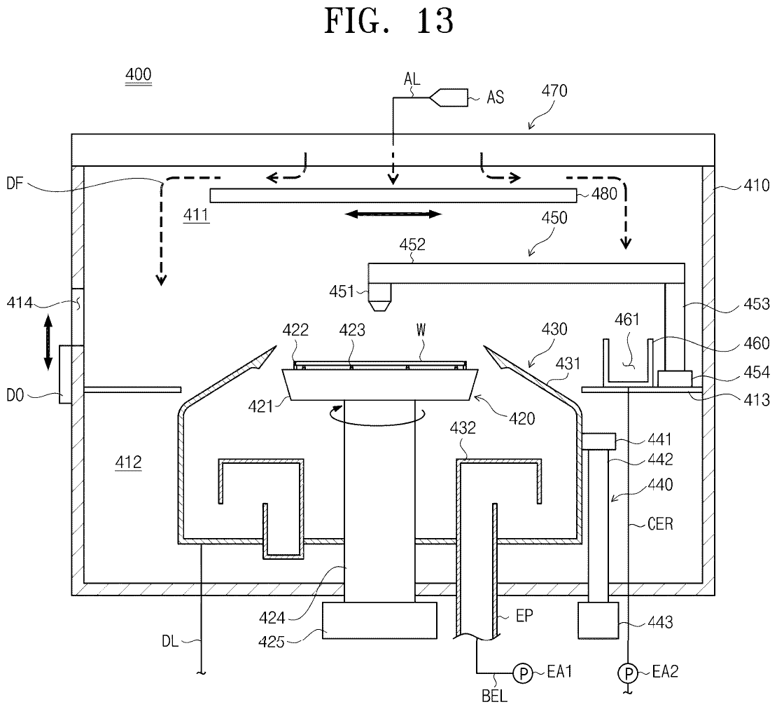

FIG. 13 is a diagram illustrating the substrate processing apparatus performing the pressure control operation of FIG. 13 according to another exemplary embodiment of the present invention.

Referring to FIG. 13, the liquid treating chamber 400 according to another exemplary embodiment of the present invention may further include a blocking plate 480. The blocking plate 480 is disposed under the downflow unit 470, and may be laterally movable. The blocking plate 480 may be moved between a blocking position facing the downflow DF supplied to the substrate W (this case corresponds to the pressure control operation), and a blocking releasing position that does not overlap with the flow path of the downflow DF supplied to the substrate W (this case corresponds to the control releasing operation). The blocking plate 480 may be configured to be laterally slidable by a power transmission mechanism, such as a motor, cylinder, or the like, not illustrated. The blocking plate 480 may be provided as a blocking plate in which no holes are formed on the side facing the top surface of the substrate W placed on the rotation plate 421.

In the examples described above, the present invention has been described based on the case where the blocking plate 480 is provided as the blocking plate in which no holes are formed as a way of example, but is not limited thereto.

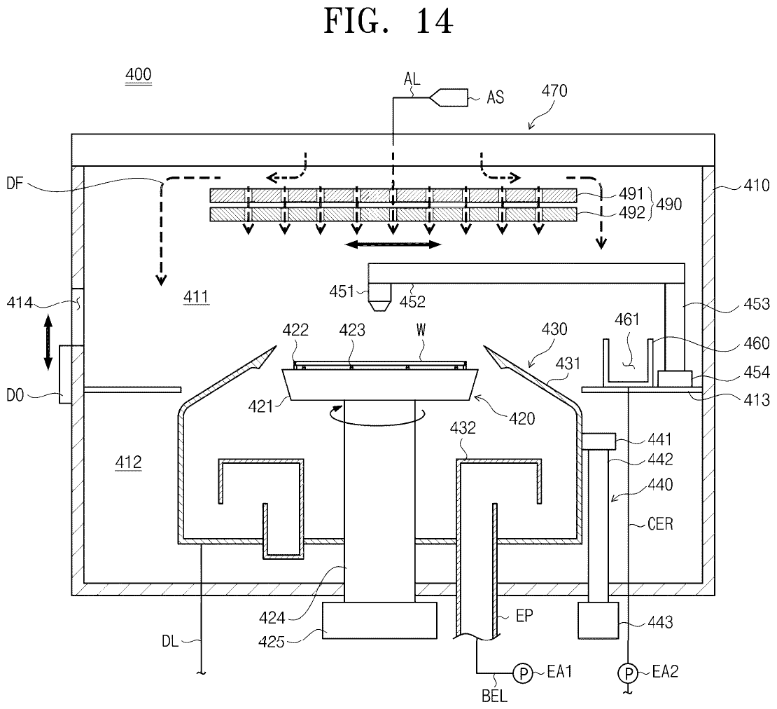

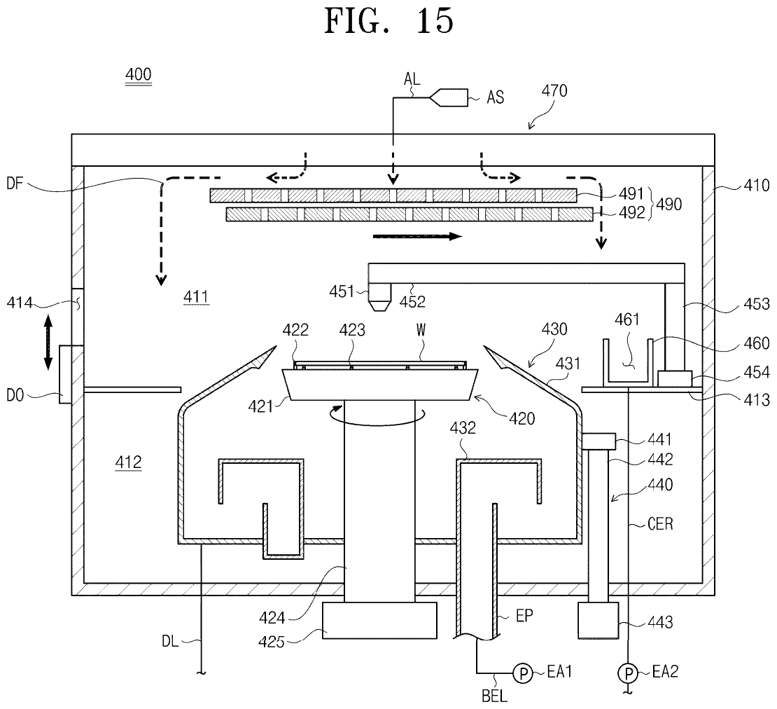

FIG. 14 is a diagram illustrating the substrate processing apparatus performing the control releasing operation according to another exemplary embodiment of the present invention, and FIG. 15 is a diagram illustrating the substrate processing apparatus performing the pressure control operation according to another exemplary embodiment of the present invention.

Referring to FIGS. 14 and 15, the liquid treating chamber 400 according to another exemplary embodiment of the present invention may include a blocking plate 490. The blocking plate 490 may include a first blocking plate 491 and a second blocking plate 492. The first blocking plate 491 and the second blocking plate 492 are disposed in an up-down direction, and the holes formed in the first blocking plate 491 and the second blocking plate 492 may or may not overlap each other, when viewed from above.

For example, when the relative positions of the first blocking plate 491 and the second blocking plate 492 are arranged in an overlapping position as illustrated in FIG. 14 (in this case, corresponding to the control releasing operation), the holes formed in the first blocking plate 491 and the holes formed in the second blocking plate 492 may overlap each other when viewed from above. In this case, the downflow DF supplied by the downflow unit 470 may pass through the blocking plate 490 and delivered to the upper region of the substrate W placed on the rotation plate 421 with no or less disturbed flow.

On the other hand, when the relative positions of the first blocking plate 491 and the second blocking plate 492 are arranged in a blocking position (in this case, corresponding to the pressure control operation), the holes formed in the first blocking plate 491 and the holes formed in the second blocking plate 492 may not overlap each other when viewed from above. In this case, the downflow DF supplied by the downflow unit 470 cannot pass through the blocking plate 490 and is blocked, and the direct flow of the downflow DF to the upper region of the substrate W placed on the rotation plate 421 may be inhibited. The position of any one of the first blocking plate 491 and the second blocking plate 492 may be fixed, and the position of any one of the first blocking plate 491 and the second blocking plate 492 may be configured to be laterally movable by a drive device (not shown), such as a motor/cylinder.

In the previously described example, the pressure in the upper region of the substrate W is reduced by shutting down the operation of the downflow unit 470, or by reducing the supply flow rate of downflow DF per unit time of the downflow unit 470, but in other exemplary embodiments of the invention, the flow of the downflow DF delivered to the upper region of the substrate W is reduced through the blocking plates 480 and 490.

In this case, less downflow DF flows to the upper region of the substrate W, and more downflow DF flows in the direction of the entrance opening 414 as the downflow DF collides the blocking plates 480 and 490 and is forced to flow laterally. In other words, the upper region of the substrate W will have a relatively low pressure and the region near the entrance opening 414 will have a relatively high pressure. In other words, the blocking plates 480 and 490 may cause the pressure in the upper region of the substrate W to be relatively low and the region near the entrance opening 414 to have a relatively high pressure.

As previously described, when the operation of the downflow unit 370 is controlled to reduce the pressure in the upper region of the substrate W, the pressure in the upper space 411 may be lower than the pressure in the transfer chamber 300, thereby potentially creating a risk of particles from the transfer chamber 300 entering the upper space 411 when the entrance opening 414 is open.

However, when the pressure in the upper region of the substrate W is adjusted by using the blocking plates 480 and 490, the pressure in the upper space 411 is equal to the pressure in the transfer chamber 300 that is the normal pressure state, or at least the region near the entrance opening 414 is higher than the pressure in the transfer chamber 300. Furthermore, in the vicinity of the entrance opening 414, the downflow DF may act as a so-called air curtain, thereby further inhibiting particles from the transfer chamber 300 from entering the upper space 411.

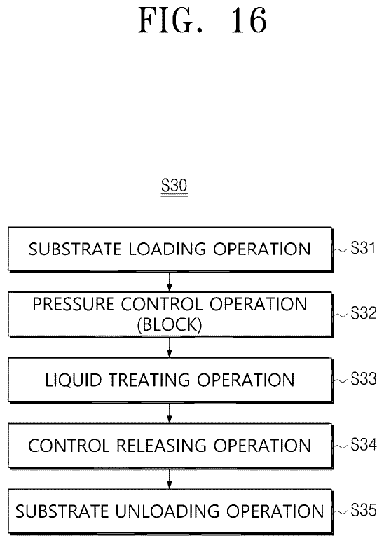

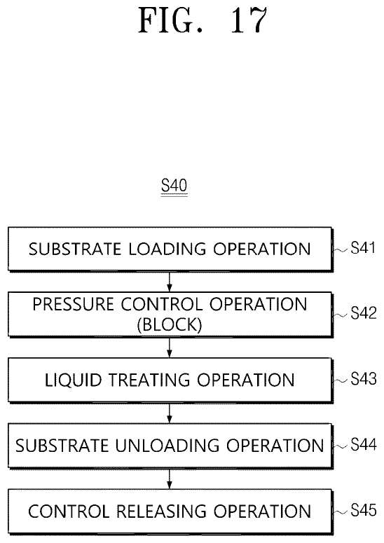

Thus, as well as a substrate processing method S30 according to a third exemplary embodiment illustrated in FIG. 16 in which a substrate loading operation S31, a pressure control operation S32, a liquid treatment operation S33, a control releasing operation S34, and a substrate unloading operation S35 are performed sequentially, even in a substrate processing method S40 according to a fourth exemplary embodiment illustrated in FIG. 17 in which a substrate loading operation S41, a pressure control operation S42, a liquid treating operation S43, a substrate unloading operation S44, and a control releasing operation S45 are performed sequentially, the possibility of particles from the transfer chamber 300 entering the upper space 411 becomes very small.

In other words, when the blocking plates 480 and 490 are utilized, there is the advantage that even when the entrance opening 414 is opened prior to the control releasing operations S34 and S45, the possibility of particles from the transfer chamber 300 entering the upper space 411 becomes very small.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A manufacturing method comprising:
a substrate loading operation of loading a substrate into a liquid treating chamber;
a liquid treating operation of supplying a treatment solution to the substrate rotating in the liquid treating chamber through a nozzle;
a substrate unloading operation of unloading the substrate from the liquid treating chamber; and
a pressure control operation of changing a pressure of a space above the substrate at least one time in a period between the substrate loading operation and the substrate unloading operation.

2. The manufacturing method of claim 1, wherein the pressure control operation includes changing the pressure of the space above the substrate to be lowered at least one time.

3. The manufacturing method of claim 2, further comprising:
a control releasing operation of increasing the pressure of the space above the substrate that was lowered in the pressure control operation.

4. The manufacturing method of claim 3, wherein the pressure control operation includes:
(a) reducing a supply rate per unit time of a downflow unit supplying downflow to the space above the substrate;
(b) interrupting an operation of the downflow unit; or
(c) increasing an exhaust volume per unit time of a treatment space in which the substrate is treated by the treatment solution to cause the pressure in the space above the substrate to be low.

5. The manufacturing method of claim 4, wherein the control releasing operation is performed after the pressure control operation and before the substrate unloading operation.

6. The manufacturing method of claim 3, wherein the pressure control operation includes disposing a blocking plate in the space above the substrate to block downflow supplied to the space above the substrate to cause the pressure in the space above the substrate to be lowered.

7. The manufacturing method of claim 6, wherein the control releasing operation is performed after the pressure control operation and before the substrate unloading operation.

8. The manufacturing method of claim 6, wherein the control releasing operation is performed after the pressure control operation and after the substrate unloading operation.

9. The manufacturing method of claim 8, wherein the blocking plate is disposed at a height equal to or higher than an entrance opening such that at least a portion of the downflow collides the blocking plate and is directed toward the entrance opening for the substrate provided in the liquid treating chamber.

10. A substrate processing method comprising:
a liquid treating operation of supplying an organic solvent to a substrate rotating in a liquid treating chamber;
a transfer operation of transferring the substrate on which the organic solvent is residual from the liquid treating chamber to a drying chamber; and
a drying operation of supplying a supercritical fluid from the drying chamber to the substrate, and removing the organic solvent residual on the substrate,
wherein a pressure control operation of reducing a pressure in a space above the substrate loaded into the liquid treating chamber at least one time during a period between loading of the substrate into the liquid treating chamber and unloading of the substrate from the liquid treating chamber.

11. The substrate processing method of claim 10, further comprising:
a control releasing operation of increasing a pressure of the space above the substrate that was lowered in the pressure control operation.

12. The substrate processing method of claim 11, wherein the pressure control operation is performed after the liquid treating operation,
the control releasing operation is performed after the substrate is unloaded from the liquid treating chamber, and
the pressure control operation includes:
(a) reducing a supply rate per unit time of a downflow unit supplying downflow to the space above the substrate;
(b) interrupting an operation of the downflow unit; or
(c) increasing an exhaust volume per unit time of a treatment space in which the substrate is treated by the treatment solution to cause the pressure in the space above the substrate to be lowered.

13. The substrate processing method of claim 11, wherein the control releasing operation is performed before the substrate is unloaded from the liquid treating chamber, and
the pressure control operation includes:
(a) reducing a supply rate per unit time of a downflow unit supplying downflow to the space above the substrate;
(b) interrupting an operation of the downflow unit; or
(c) increasing an exhaust volume per unit time of a treatment space in which the substrate is treated by the treatment solution to cause the pressure in the space above the substrate to be lowered.

14. The substrate processing method of claim 11, wherein the control releasing operation is performed before or after the substrate is unloaded from the liquid treating chamber, and
the pressure control operation includes disposing a blocking plate in the space above the substrate to block downflow supplied to the space above the substrate to cause the pressure in the space above the substrate to be lowered.

15. The substrate processing method of claim 10, wherein the organic solvent is isopropyl alcohol.

16.-20. (canceled)
